(19) United States
(12) Patent Application Publication
(10) Pub. No.: US 2012/0050966 A1
(43) Pub. Date: Mar. 1, 2012

(54) ELECTRONIC DEVICE ASSEMBLY

(75) Inventors: Bo-Wen LIU, New Taipei City (TW); Chin-Lung FAN, New Taipei City (TW)

(73) Assignee: WINSTRON CORPORATION, New Taipei City (TW)

(21) Appl. No.: 13/155,208

(22) Filed: Jun. 7, 2011

(30) Foreign Application Priority Data
Sep. 1, 2010 (TW) 099216949

(51) Int. Cl. H05K 5/00

(52) U.S. Cl. 361/679.01

(57) ABSTRACT

An electronic device assembly includes an electronic device and a support mechanism. The electronic device has a bottom surface, and at least one positioning groove formed in the bottom surface. The support mechanism includes first and second support members. The first support member has opposite first and second connecting ends. The first connecting end is pivotally connected to the bottom surface, is spaced apart from the positioning groove in a longitudinal direction, and is disposed rearwardly of the positioning groove. The second support member has a third connecting end and an engaging end opposite to the third connecting end. The third connecting end is pivotally connected to the second connecting end. The engaging end is removably engageable to the positioning groove such that the first and second support members are inclined protrudingly relative to the bottom surface in a supporting position when the engaging end is engaged to the positioning groove.

### CROSS-REFERENCE TO RELATED APPLICATION

This application claims priority of Taiwanese Application No. 099216949, filed on Sep. 1, 2010.

### BACKGROUND OF THE INVENTION

1. Field of the Invention

The invention relates to an electronic device, more particularly to an electronic device assembly with a support mechanism so as to facilitate heat-dissipation.

2. Description of the Related Art

As illustrated in FIG. 1 and FIG. 2, Taiwanese Utility Model Patent No. M368115 (Taiwanese Patent Application No. 098208891) discloses a conventional heat-dissipating device for a notebook computer. The conventional heat-dissipating device includes a main body 11 and a heat-dissipating fan 12. A top surface of the main body 11 is adapted for placing a notebook computer (not shown) thereon such that the notebook computer is elevated and supported by the main body 11. The heat-dissipating fan 12 is mounted to the main body 11 via a plurality of screw fasteners 13 such that the heat-dissipating fan 12 can facilitate heat dissipation of a bottom portion of the notebook computer.

However, this conventional heat-dissipating device is bulky, and takes up relatively large space. Therefore, it is not suitable for portable use.

### SUMMARY OF THE INVENTION

Therefore, one object of the present invention is to provide an electronic device assembly that is provided with a support mechanism. By disposing the support mechanism in a supporting position, a heat-dissipating space can be formed between an electronic device of the electronic device assembly and a tabletop or the like for air to flow therethrough to thereby enhance heat-dissipating efficiency.

Another object of the present invention is to provide an electronic device assembly that is provided with a support mechanism, in which when the support mechanism is disposed in a leveled position, the electronic device assembly remains compact, and is convenient for portable use by a user.

According to the present invention, there is provided an electronic device assembly that includes an electronic device and a support mechanism. The electronic device has a bottom surface, and at least one first positioning groove formed in the bottom surface. The support mechanism includes a first support member and a second support member. The first support member has a first connecting end and a second connecting end opposite to the first connecting end. The first connecting end is pivotally connected to the bottom surface of the electronic device, is spaced apart from the first positioning groove in a longitudinal direction, and is disposed rearwardly of the first positioning groove. The second support member has a third connecting end and an engaging end opposite to the third connecting end. The third connecting end is pivotally connected to the second connecting end of the first support member. The engaging end is removably engageable to the first positioning groove such that the first and second support members are inclined protrudingly relative to the bottom surface in a supporting position when the engaging end is engaged to the first positioning groove.

Preferably, the electronic device further has at least one second positioning groove formed in the bottom surface, spaced apart from the first positioning groove in the longitudinal direction, and disposed forwardly of the first positioning groove. The engaging end of the second support member is removably engageable to the second positioning groove such that the first and second support members are leveled with the bottom surface of the electronic device in a leveled position when the engaging end is engaged to the second positioning groove.

In addition, the electronic device further has a receiving channel that is formed in the bottom surface, that is in spatial communication with the first and second positioning grooves, and that receives the first and second support members when the first and second support members are disposed in the leveled position.

In one implementation, one of the second connecting end of the first support member and the third connecting end of the second support member includes two connecting pins that are spaced apart from each other, and the other one of the second connecting end of the first support member and the third connecting end of the second support member is formed with two connecting slots for engaging the connecting pins, respectively.

In another implementation, one of the second connecting end of the first support member and the third connecting end of the second support member is formed with two connecting slots that are spaced apart from each other, and the other one of the second connecting end of the first support member and the third connecting end of the second support member is formed with a through hole that is aligned with the connecting slots. The support mechanism further includes a pin that extends through the connecting slots and the through hole for connecting pivotally the second and third connecting ends.

Preferably, the electronic device has two of the first positioning grooves that are spaced apart from each other in a horizontal direction, and two of the second positioning grooves that are spaced apart from each other in the horizontal direction. The engaging end of the second support member has two engaging portions that are spaced apart from each other in the horizontal direction, and that are each removably engageable to a corresponding one of the first positioning groove and a corresponding one of the second positioning grooves.

Through the above-described technical means, the electronic device assembly of the present invention achieves the following advantages and effects. Through the support mechanism designed in such a manner, when the first and second support members are disposed in the leveled position, where the first and second support members are received in the receiving channel, the size of the electronic device assembly is not increased and remains fairly compact, such that the electronic device assembly is portable. In addition, the first and second support members are protected from accidental collisions to thereby prevent the engaging end of the second support member from being knocked out of engagement with the second positioning groove. When the first and second support members are disposed in the supporting position, the electronic device is inclinedly supported on a tabletop or the like such that a heat-dissipating space is formed between the electronic device and the tabletop or the like for air to flow therethrough to thereby enhance heat dissipation of the electronic device.

### BRIEF DESCRIPTION OF THE DRAWINGS

Other features and advantages of the present invention will become apparent in the following detailed description of the embodiments with reference to the accompanying drawings, of which:

FIG. 1 is a perspective view of a conventional heat-dissipating device according to Taiwanese Utility Model Patent No. M368115;

FIG. 2 is another perspective view of the conventional heat-dissipating device;

FIG. 3 is a top perspective view of the first embodiment of an electronic device assembly according to the present invention;

FIG. 4 is a bottom perspective view of the first embodiment, illustrating first and second support members of a support mechanism disposed in a leveled position;

FIG. 5 is a partly exploded bottom perspective view of the first embodiment, illustrating connecting relationship between the first and second support members of the support mechanism;

FIG. 6 is a fragmentary enlarged view of the first embodiment, illustrating the first and second support members disposed in the leveled position;

FIG. 7 is a schematic side view of the first embodiment, illustrating the first and second support members disposed in the leveled position;

FIG. 8 is a schematic side view of the first embodiment for illustrating moving the first and second support members from the leveled position to a supporting position;

FIG. 9 is another schematic side view similar to FIG. 8;

FIG. 10 is a fragmentary enlarged view of the first embodiment, illustrating the first and second support members disposed in the supporting position;

FIG. 11 is a schematic side view of the first embodiment, illustrating the first and second support members disposed in the supporting position;

FIG. 12 is a partly exploded perspective bottom view of the second embodiment of an electronic device assembly according to the present invention, illustrating connecting relationship between the first and second support members; and

FIG. 13 is a fragmentary enlarged view of the second embodiment, illustrating the first and second support members disposed in the supporting position.

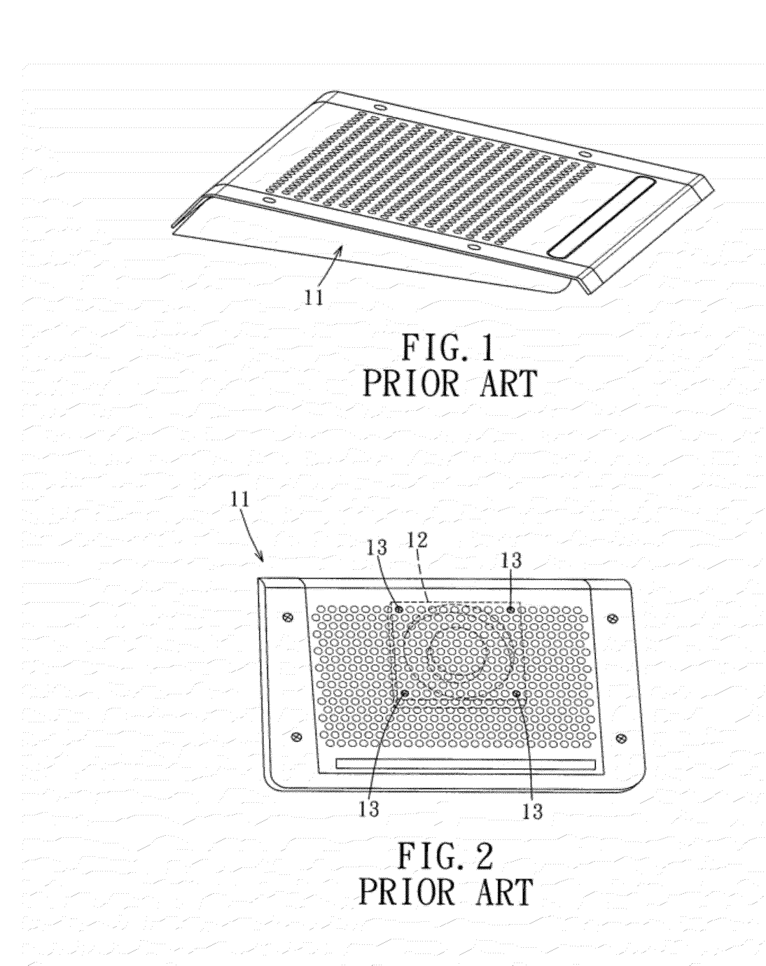

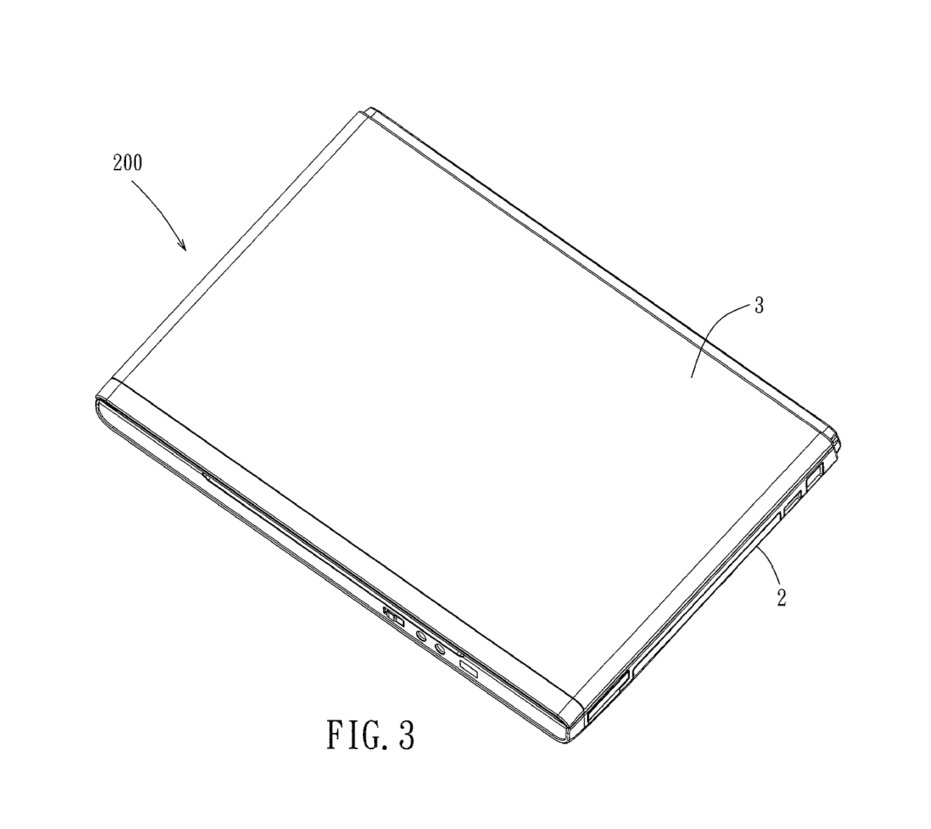

### DETAILED DESCRIPTION OF THE PREFERRED EMBODIMENTS

Before the present invention is described in greater detail, it should be noted that like elements are denoted by the same reference numerals throughout the disclosure.

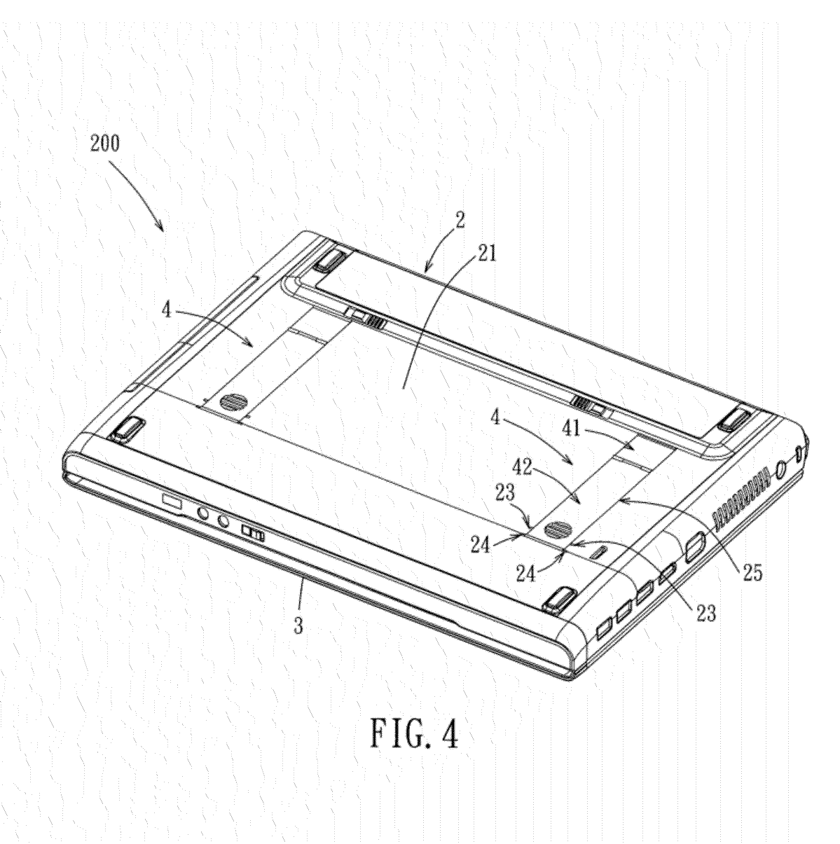

With reference to FIG. 3 and FIG. 4, the first embodiment of an electronic device assembly 200 according to the present invention is exemplified as a notebook computer assembly. The electronic device assembly 200 includes an electronic device 2, a display screen 3 coupled pivotally to a rear end of the electronic device 2, and two support mechanisms 4. It should be noted herein that the electronic device assembly 200 can also be a tablet computer or the like in other embodiments of the present invention.

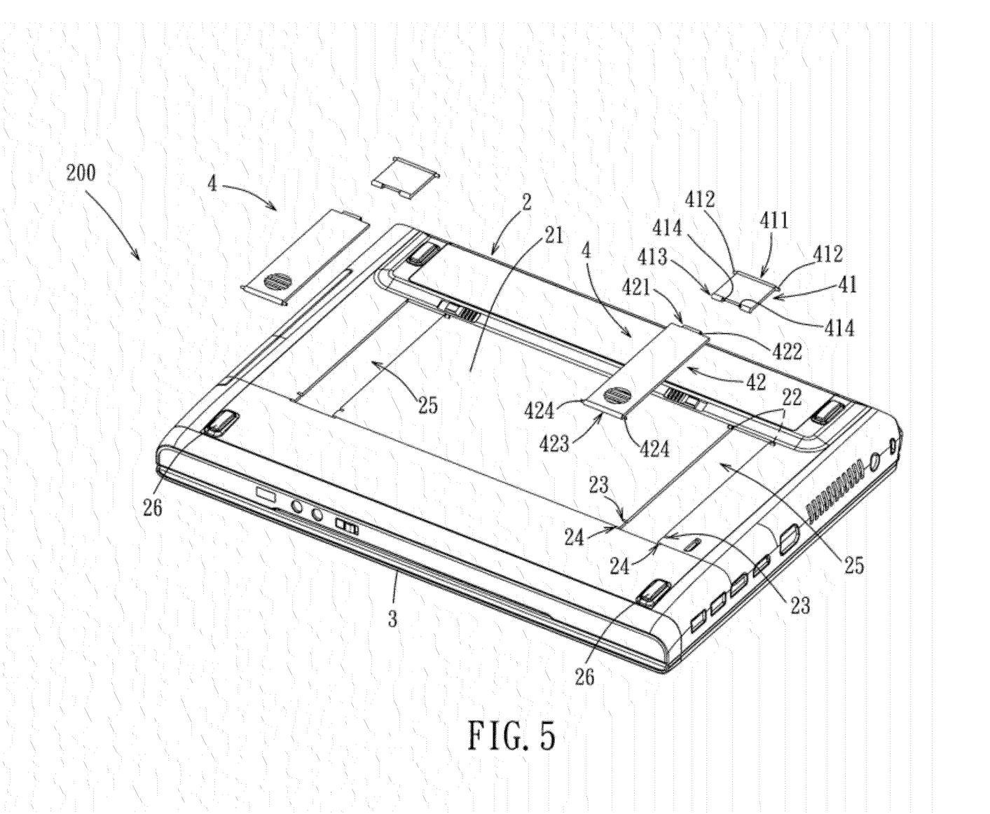

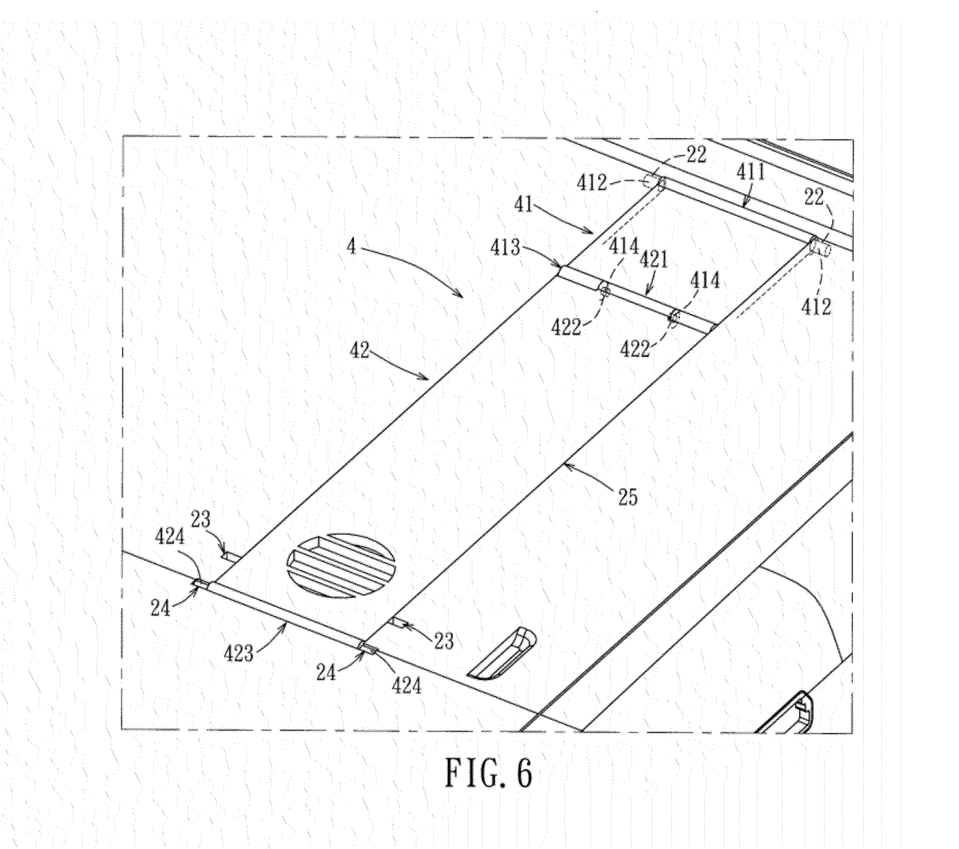

With reference to FIG. 4, FIG. 5 and FIG. 6, the electronic device 2 has a bottom surface 21. Each of the support mechanisms 4 includes a first support member 41 and a second support member 42. The first support member 41 is rectangular in shape, and has a first connecting end 411 pivotally connected to the bottom surface 21 of the electronic device 2. The first connecting end 411 has two protruding pins 412 that are spaced apart from each other in a horizontal direction. The electronic device 2 further has two pairs of grooves 22 that are formed in the bottom surface 21, and that are spaced apart from each other in the horizontal direction. Each pair of the grooves 22 correspond in location to the protruding pins 412 of the first support member 41 of a corresponding one of the support mechanisms 4. The grooves 22 are disposed proximate to a rear side of the bottom surface 21. By having the protruding pins 412 respectively and rotatably engaging the grooves 22, the first support member 41 of the corresponding one of the support mechanisms 4 can pivot relative to the bottom surface 21 of the electronic device 2. The first support member 41 of each of the support mechanisms 4 further has a second connecting end 413 opposite to the first connecting end 411. The second support member 42 is rectangular in shape, and is longer than the first support member 41. The second support member 42 of each of the support mechanisms 4 has a third connecting end 421 pivotally connected to the second connecting end 413 of the first support member 41 of the corresponding one of the support mechanisms 4. In this embodiment, the second connecting end 413 of the first support member 41 includes two connecting pins 414 that are spaced apart from each other in the horizontal direction, and the third connecting end 421 of the second support member 42 is formed with two connecting slots 422 that are spaced apart from each other in the horizontal direction. By having the connecting pins 414 rotatably engaging the connecting slots 422, the second support member 42 can pivot relative to the first support member 41.

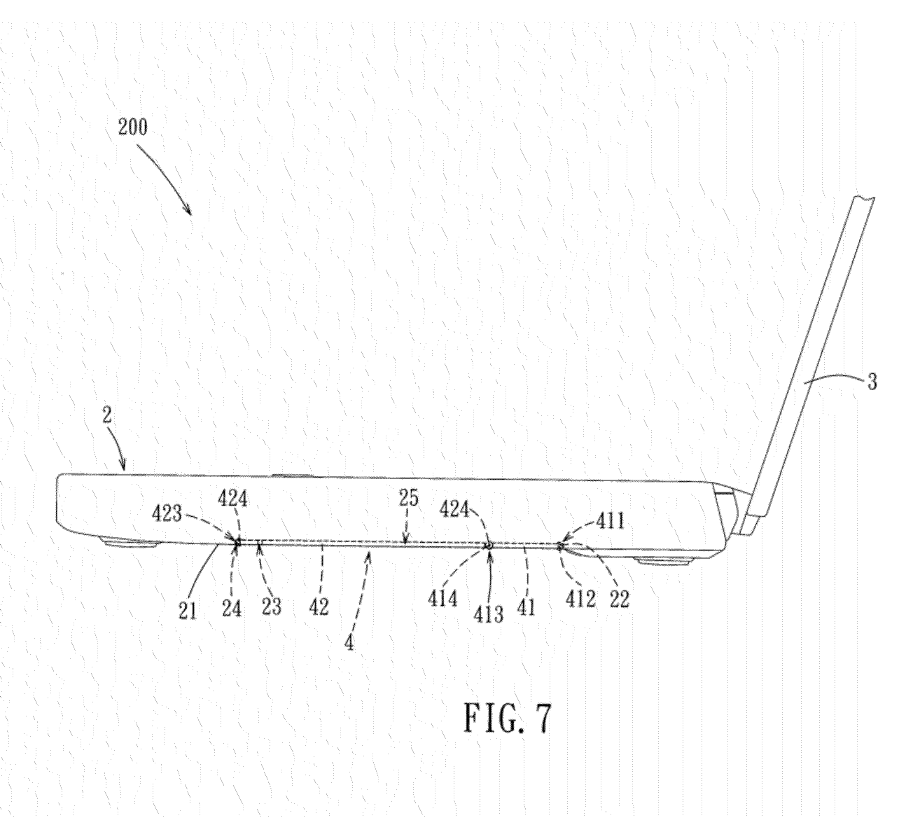

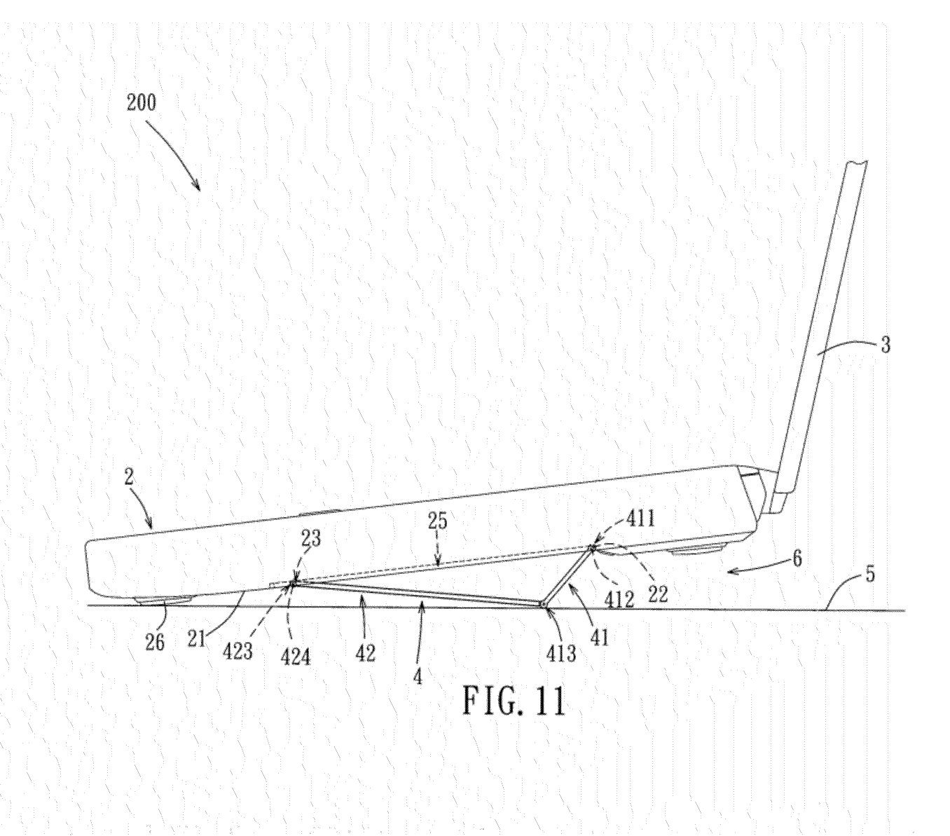

Moreover, the second support member 42 further has an engaging end 423 opposite to the third connecting end 421. The engaging end 423 has two engaging portions 424 that are spaced apart from each other in the horizontal direction. The electronic device 2 has two pairs of first positioning grooves 23 formed in the bottom surface 21 and spaced apart from each other in the horizontal direction, and two pairs of second positioning grooves 24 formed in the bottom surface 21 and spaced apart from each other in the horizontal direction. The first connecting end 411 of the first support member 41 of each of the support mechanisms 4 is spaced apart from the corresponding pair of the first positioning grooves 23 in a longitudinal direction, and is disposed rearwardlly of the corresponding pair of the first positioning grooves 23. The second positioning grooves 24 are spaced apart from the first positioning grooves 23 in the longitudinal direction, and are disposed forwardly of the first positioning grooves 23. The engaging portions 424 of the engaging end 423 of the second support member 42 are each removably engageable to a corresponding one of the first positioning grooves 23 such that the first and second support members 41, 42 of each of the support mechanisms 4 are inclined protrudingly relative to the bottom surface 21 of the electronic device 2 in a supporting position when the engaging portions 424 of the engaging end 423 of the second support member 42 of the corresponding support mechanism 4 are respectively engaged to the corresponding pair of the first positioning grooves 23 (as shown in FIG. 11). In addition, the engaging portions 424 of the engaging end 423 are each removably engageable to a corresponding one of the second positioning grooves 24 such that the first and second support members 41, 42 of each of the support mechanisms 4 are leveled with the bottom surface 21 of the electronic device 2 in a leveled position when the engaging portions 424 of the engaging end 423 of the second support member 42 of the corresponding support mechanism 4 are respectively engaged to the corresponding pair of the second positioning grooves 24 (as shown in FIG. 7).

Preferably, the electronic device 2 further has two receiving channels 25 that are formed in the bottom surface 21, and that are spaced apart from each other in the horizontal direction. Each of the receiving channels 25 is rectangular in shape, and is disposed in spatial communication with a corresponding pair of the first positioning grooves 23 and a corresponding pair of the second positioning grooves 24. Each of the receiving channels 25 is capable of receiving the first and second support members 41, 42 of a corresponding one of the support mechanisms 4. When the first and second support members 41, 42 of each of the support mechanisms 4 are disposed in the leveled position, the corresponding one of the receiving channels 25 receives the first and second support members 41, 42 such that the first and second support members 41, 42 are leveled with the bottom surface 21 of the electronic device 2 so as to protect the first and second support members 41, 42 from accidental collisions to thereby prevent the engaging portions 424 of the engaging end 423 of the second support member 42 from being knocked out of engagement with the corresponding pair of the second positioning grooves 24. As such, the first and second support members 41, 42 can be securely maintained in the leveled position.

With reference to FIG. 4, FIG. 6 and FIG. 7, when the engaging portions 424 of the engaging end 423 of the second support member 42 of each of the support mechanisms 4 are respectively engaged to the corresponding pair of the second positioning grooves 24, the first and second support members 41, 42 are disposed in the leveled position where the same are received in the corresponding one of the receiving channels 25. Consequently, the electronic device assembly 200 of the present invention remains compact, thereby facilitating storage and convenient transport. Moreover, during transport of the electronic device assembly 200, the first and second support members 41, 42 of the support mechanisms 4 are protected from accidental collisions to thereby prevent the engaging portions 424 of the engaging ends 423 of the second support members 42 from being knocked out of engagement with the respective second positioning grooves 24.

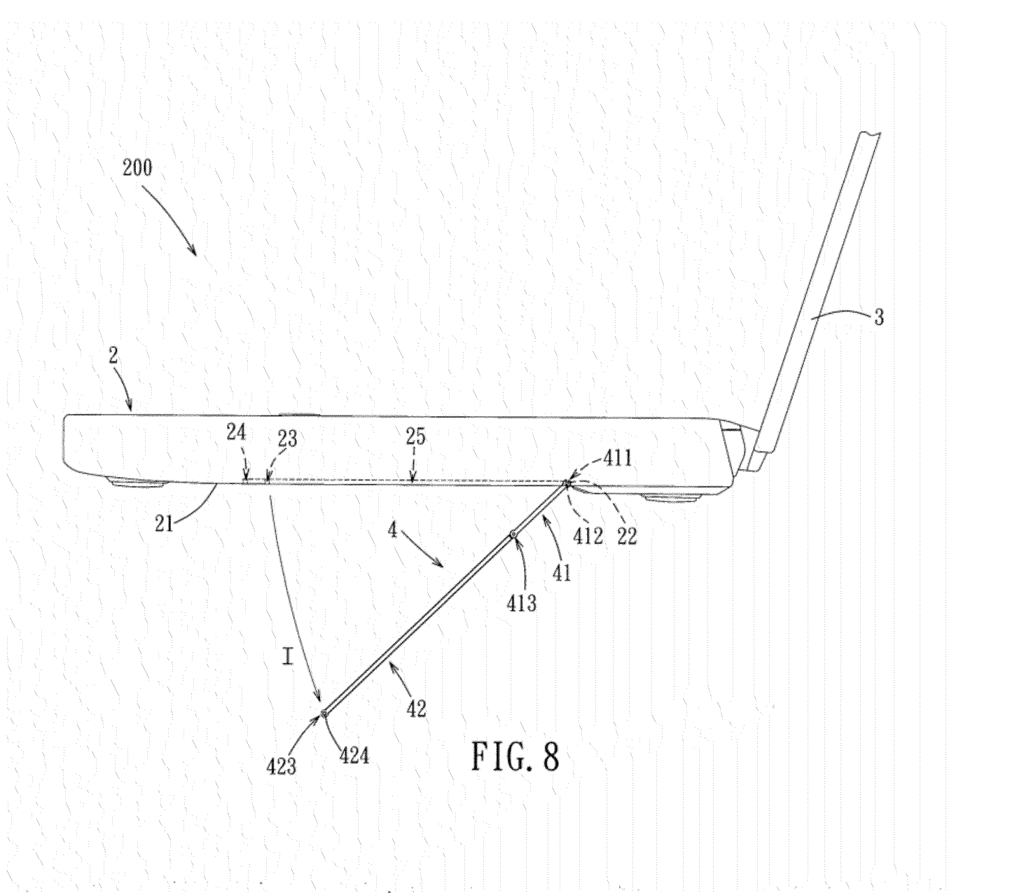

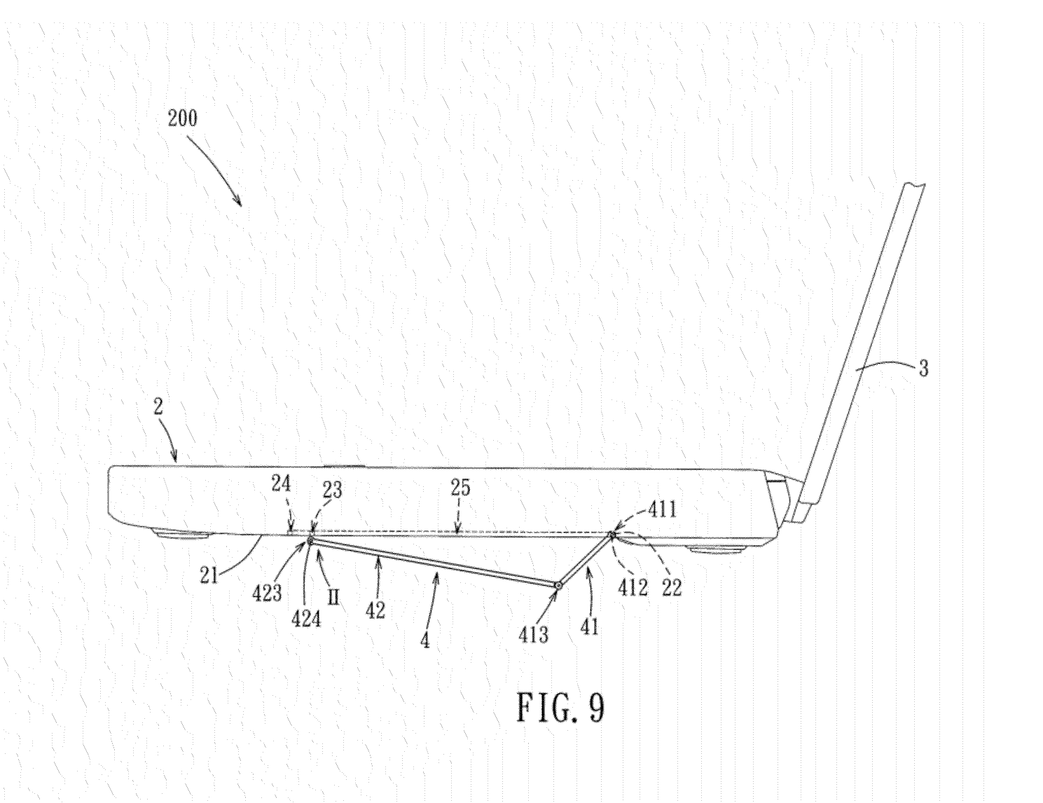

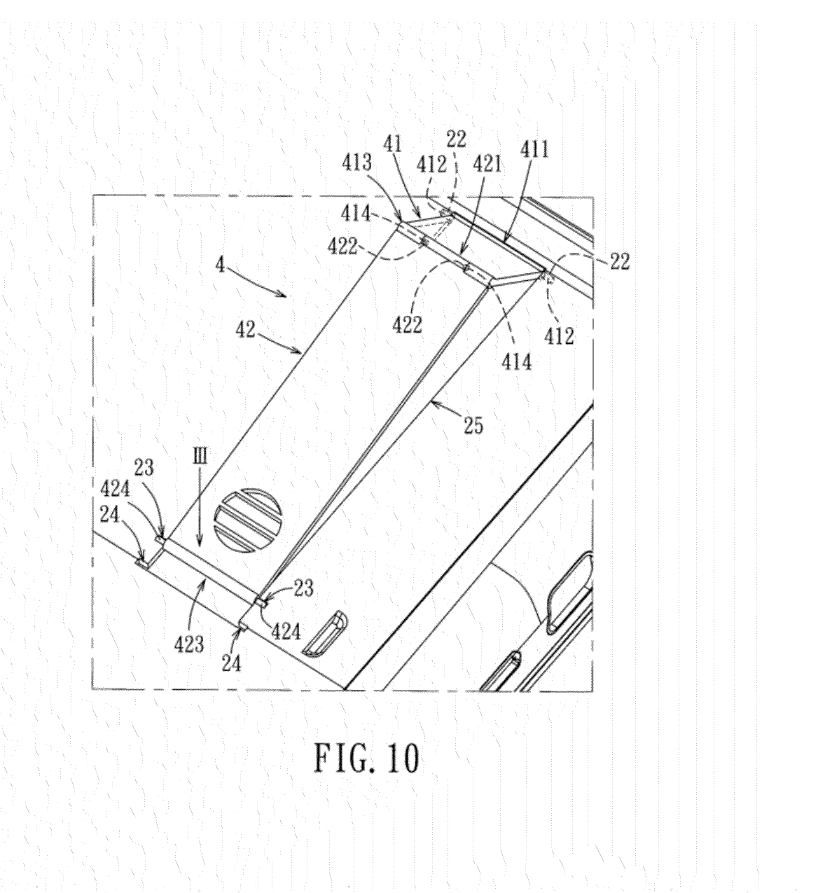

With reference to FIG. 8, FIG. 9 and FIG. 10, when the user wishes to use the electronic device assembly 200, each of the support mechanisms 4 is moved into a state of use, where the first and second support members 41, 42 are disposed in the supporting position. The following description is provided with respect to a single support mechanism 4. First, the engaging end 423 of the second support member 42 is pulled in the direction shown by arrow (I) so as to disengage the engaging portions 424 of the engaging end 423 from the corresponding pair of the second positioning grooves 24 such that the first and second support members 41, 42 are pivotable relative to the electronic device 2 about the first connecting end 411. When the first and second support members 41, 42 are pivoted to a suitable angle, the second support member 42 is moved in the direction shown by arrow (II) so as to be pivoted relative to the first support member 41 at the junction between the second and third connecting ends 413, 421 until the engaging portions 424 of the engaging end 423 of the second support member 42 are aligned with the corresponding pair of the first positioning grooves 23. Finally, the engaging end 423 of the second support member 42 is pressed in the direction shown by arrow (III) toward the corresponding one of the receiving channels 25 so as to move the engaging portions 424 of the engaging end 423 into engagement with the corresponding pair of the first positioning grooves 23. At this point, the first and second support members 41, 42 are disposed in the supporting position.

As shown in FIG. 10 and FIG. 11, when the first and second support members 41, 42 of each of the support mechanisms 4 are disposed in the supporting position, the user can put the electronic device assembly 200 on a tabletop 5 or the like for use. Since the first and second support members 41, 42 are inclined protrudingly relative to the bottom surface 21 of the electronic device 2 in the supporting position, and since the first and second support members 41, 42 define an included angle therebetween, the electronic device assembly 200 is supported on the tabletop 5 by multiple foot pads 26 that are disposed proximate to a front side of the electronic device 2 and by the support mechanisms 4. Consequently, the electronic device 2 is inclined relative to the tabletop 5, and forms a heat-dissipating space 6 with the tabletop 5 for air to flow therethrough to thereby enhance heat-dissipating efficiency of the electronic device 2. It should be noted herein that, with the protruding pins 412 of the first connecting ends 411 respectively engaging the grooves 22 in the bottom surface 21, and with the engaging portions 424 of the engaging ends 423 of the second support members 42 respectively engaging the first positioning grooves 23 formed in the bottom surface 21 of the electronic device 2, when the user presses downwardly on the electronic device 2, e.g., through typing on a keyboard (not shown), the downward force can be evenly passed down to the first support members 41 via the protruding pins 412 and to the second support members 42 via the engaging portions 424. In addition, the protruding pins 412 of the first support members 41 and the engaging portions 424 of the second support members 42 can evenly support the weight of the electronic device 2, thereby reducing the possibility of fracture of the protruding pins 412 and the engaging portions 424 due to uneven force distribution, and enhancing stability and reliability of first support members 4 and the second support members 42 when disposed in the supporting position.

With reference to FIG. 8, FIG. 9 and FIG. 10, when it is desired to move the first and second support members 41, 42 of one of the support mechanisms 4 from the supporting position to the leveled position, the second support member 42 is first pulled in a direction opposite to that shown by arrow (III) so as to remove the engaging end 423 from the corresponding one of the receiving channels 25 and to disengage the engaging portions 424 of the engaging end 423 from the corresponding pair of the first positioning grooves 23. Then, the second support member 42 is pivoted in a direction opposite to that shown by arrow (II) such that the second support member 42 extends in the same direction as the first support member 41. Finally, the first and second support members 41, 42 are pivoted in a direction opposite to that shown by arrow (I) so as to move the first and second support members 41, 42 into the corresponding one of the receiving channels 25 until the engaging portions 424 of the engaging end 423 of the second support member 42 engages the corresponding pair of the second positioning grooves 24. At this time, the first and second support members 41, 42 are disposed in the leveled position. It should be noted herein that, although the electronic device assembly 200 is shown to comprise two of the support mechanisms 4 in this embodiment for illustration, the electronic device assembly 200 may have only one support mechanism 4, which is preferably disposed at a central part of the bottom surface 21 of the electronic device 2, in other embodiments of the present invention. Moreover, the number of the engaging portions 424 of the engaging end 423 of the second support member 42 of each support mechanism 4 may also be one, and accordingly the number of each of the first and second positioning grooves 23, 24 corresponding to a single support mechanism 4 may also be one. It should be further noted herein that although it is shown in this embodiment that the second connecting end 413 of the first support member 41 includes the connecting pins 414 and that the third connecting end 421 of the second support member 42 is formed with the connecting slots 422 for engaging the connecting pins 414, the present invention also encompasses the arrangement where the second connecting end 413 is formed with the connecting slots and the third connecting end 421 is formed with the connecting pins.

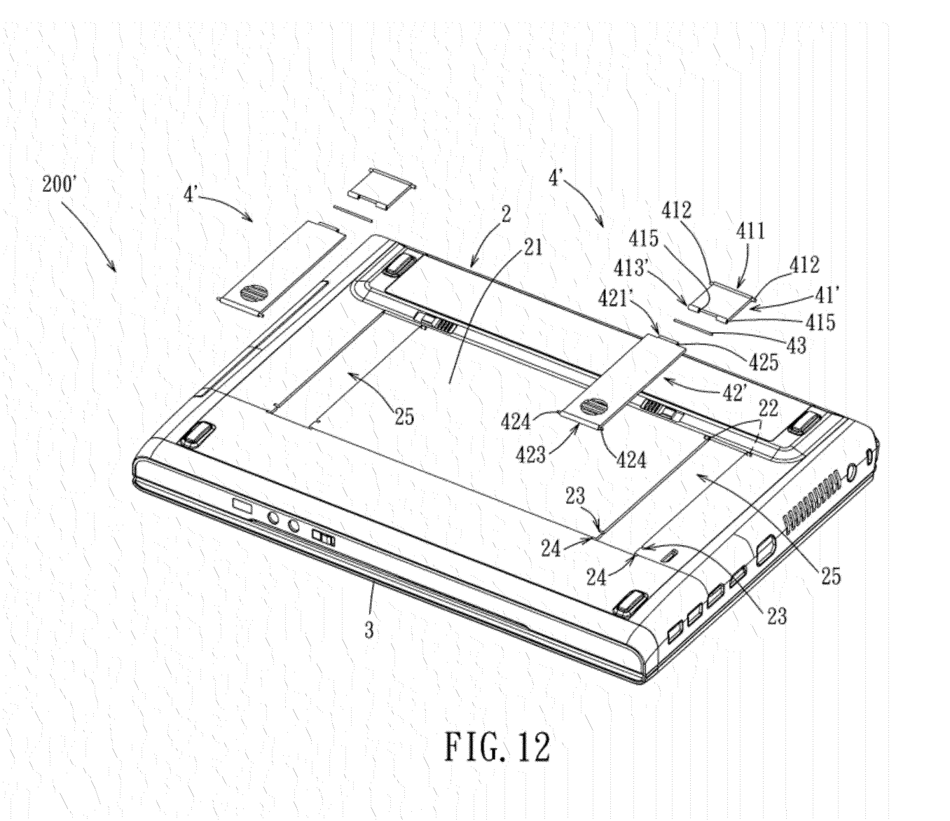

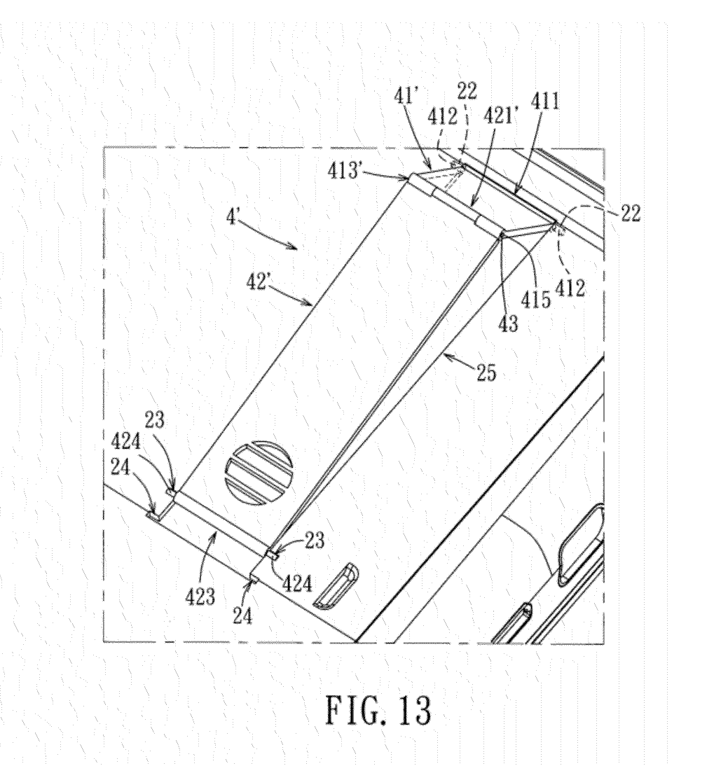

As illustrated in FIG. 12 and FIG. 13, the second embodiment of an electronic device assembly 200′ according to the present invention differs from the first embodiment in the designs of the second connecting end 413′ of the first support member 41′ and the third connecting end 421′ of the second support member 42′.

According to the second embodiment, the second connecting end 413′ of the first support member 41′ is formed with two connecting slots 415 that are spaced apart from each other in the horizontal direction, and the third connecting end 421′ of the second support member 42′ is formed with a through hole 425 that is aligned with the connecting slots 415. Each of the support mechanisms 4′ further includes a pin 43 that extends through the connecting slots 415 and the through hole 425 for connecting pivotally the second and third connecting ends 413′, 421′. It should be noted herein that the present invention also encompasses the arrangement where the third connecting end 421′ is formed with two connecting slots and the second connecting end 413′ is formed with a through hole that is aligned with the connecting slots.

In summary, through the design of the support mechanisms 4 (4′), the electronic device assembly 200 (200′) according to the present invention can be easily stored or transported when the first and second support members 41 (41′), 42 (42′) are disposed in the leveled position, where the same are received in the receiving channels 25, while maintaining the compact size of the electronic device assembly 200 (200′). In addition, the first and second support members 41 (41′), 42 (42′) are protected from accidental collisions to thereby prevent the engaging portions 424 of the engaging end 423 of the second support member 42 (42′) from being knocked out of engagement with the second positioning grooves 24 in the bottom surface 21 of the electronic device 2. On the other hand, when the first and second support members 41 (41′), 42 (42′) are disposed in the supporting position, where the first and second support members 41 (41′), 42 (42′) are inclined protrudingly relative to the bottom surface 21 of the electronic device 2, the electronic device 2 can be inclinedly supported on a tabletop 5 or the like such that a heat-dissipating space 6 is formed between the electronic device 2 and the tabletop 5 for air to flow therethrough to thereby enhance heat dissipation of the electronic device 2.

While the present invention has been described in connection with what are considered the most practical and embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An electronic device assembly comprising:
an electronic device having a bottom surface, and at least one first positioning groove formed in said bottom surface; and
a support mechanism including
a first support member that has a first connecting end and a second connecting end opposite to said first connecting end, said first connecting end being pivotally connected to said bottom surface of said electronic device, being spaced apart from said first positioning groove in a longitudinal direction, and being disposed rearwardly of said first positioning groove, and
a second support member that has a third connecting end and an engaging end opposite to said third connecting end, said third connecting end being pivotally connected to said second connecting end of said first support member, said engaging end being removably engageable to said first positioning groove, said first and second support members being inclined protrudingly relative to said bottom surface in a supporting position when said engaging end is engaged to said first positioning groove.

2. The electronic device assembly as claimed in claim 1, wherein said electronic device further has at least one second positioning groove formed in said bottom surface, spaced apart from said first positioning groove in the longitudinal direction, and disposed forwardly of said first positioning groove, said engaging end of said second support member being removably engageable to said second positioning groove, said first and second support members being leveled with said bottom surface of said electronic device in a leveled position when said engaging end is engaged to said second positioning groove.

3. The electronic device assembly as claimed in claim 2, wherein said electronic device further has a receiving channel that is formed in said bottom surface, and that is in spatial communication with said first and second positioning grooves, said receiving channel receiving said first and second support members when said first and second support members are disposed in the leveled position.

4. The electronic device assembly as claimed in claim 3, wherein one of said second connecting end of said first support member and said third connecting end of said second support member includes two connecting pins that are spaced apart from each other, and the other one of said second connecting end of said first support member and said third connecting end of said second support member is formed with two connecting slots for engaging said connecting pins, respectively.

5. The electronic device assembly as claimed in claim 3, wherein one of said second connecting end of said first support member and said third connecting end of said second support member is formed with two connecting slots that are spaced apart from each other, and the other one of said second connecting end of said first support member and said third connecting end of said second support member is formed with a through hole that is aligned with said connecting slots, said support mechanism further including a pin that extends through said connecting slots and said through hole for connecting pivotally said second and third connecting ends.

6. The electronic device assembly as claimed in claim 3, wherein said electronic device has two of said first positioning grooves that are spaced apart from each other in a horizontal direction, and two of said second positioning grooves that are spaced apart from each other in the horizontal direction, said engaging end of said second support member having two engaging portions that are spaced apart from each other in the horizontal direction, and that are each removably engageable to a corresponding one of said first positioning groove and a corresponding one of said second positioning grooves.
